(19) United States
(12) Patent Application Publication
(10) Pub. No.: US 2026/0063712 A1
(43) Pub. Date: Mar. 5, 2026

(54) INTEGRATED CIRCUIT AND ABNORMALITY HISTORY MANAGEMENT METHOD

(71) Applicant: Fujikura Ltd., Tokyo (JP)

(72) Inventor: Ken Sakuma, Sakura-shi (JP)

(73) Assignee: Fujikura Ltd., Tokyo (JP)

(21) Appl. No.: 19/297,257

(22) Filed: Aug. 12, 2025

(30) Foreign Application Priority Data
Sep. 2, 2024 (JP) 2024-150599

(51) Int. Cl. G01R 31/317; H03F 3/24

(52) U.S. Cl. CPC G01R 31/31724; G01R 31/31721; H03F 3/245; H03F 2200/294; H03F 2200/451

(57) ABSTRACT

An integrated circuit and an abnormality history management method, the integrated circuit includes an abnormality detection circuit configured to not only to detect the presence or absence of an abnormality but also to be capable of knowing whether the detected abnormality is still continuing or has already been resolved; a first storage region configured to store first information indicating a latest detection result of the abnormality detection circuit; and a second storage region configured to be provided corresponding to the first storage region and stores second information indicating a detection history of the abnormality detected by the abnormality detection circuit.

### CROSS-REFERENCE TO RELATED APPLICATION

Priority is claimed on Japanese Patent Application No. 2024-150599, filed Sep. 2, 2024, the content of which is incorporated herein by reference.

### BACKGROUND OF THE INVENTION

### Field of the Invention

The present invention relates to an integrated circuit and an abnormality history management method.

### Description of Related Art

Some integrated circuits are capable of detecting an abnormal state. For example, some radio frequency integrated circuits used in wireless communication devices include a power detector (PD) in a path from a power amplifier (PA) to an antenna, and can detect an abnormality in power of a wireless signal transmitted from the antenna according to a detection result of the power detector. Some of such integrated circuits store information indicating the detection result of the abnormal state.

The specification of the following U.S. Pat. No. 11,035,890 discloses an abnormality detection data recording device that can detect an abnormality and maintain the history thereof. The abnormality detection data recording device includes a first semiconductor integrated circuit device and a second semiconductor integrated circuit device, transmits abnormality detection data indicating an abnormality detected by the first semiconductor integrated circuit device to the second semiconductor integrated circuit device, and stores the abnormality detection data in the second semiconductor integrated circuit device.

### SUMMARY OF THE INVENTION

By the way, in the integrated circuit capable of storing the information indicating an abnormality as in the technology disclosed in the above-described Patent Document 1, it is possible to know what kind of abnormality has occurred by referring to the recorded information.

However, even by referring to the recorded information, it is not possible to know whether the abnormal state is still continuing or whether the abnormal state is temporary and the abnormal state has already been resolved.

The present invention has been made in view of the above circumstances, and an object of the present invention is to provide an integrated circuit and an abnormality history management method capable of knowing the occurrence of an abnormal state and knowing whether or not the abnormal state is continuing.

In order to solve the above-described problem, an integrated circuit according to a first aspect of the present invention includes: an abnormality detection circuit configured to detect presence or absence of an abnormality; a first storage region configured to store first information indicating a latest detection result of the abnormality detection circuit; and a second storage region configured to be provided corresponding to the first storage region and stores second information indicating a detection history of the abnormality detected by the abnormality detection circuit.

In the integrated circuit according to one aspect of the present invention, the first information indicating the latest detection result of the abnormality detection circuit that detects the presence or absence of an abnormality is stored in the first storage region, and the second information indicating the detection history of the abnormality detected by the abnormality detection circuit is stored in the second storage region provided corresponding to the first storage region. Accordingly, it is possible to know the occurrence of an abnormal state and to know whether or not the abnormal state is continuing.

According to an integrated circuit according to a second aspect of the present invention, in the integrated circuit according to the first aspect of the present invention, the second information stored in the second storage region may be deleted during an initialization operation of a storage region including the second storage region or in a case where a communication telegram for specifying an address of the second storage region and instructing to delete the second information is received.

According to an integrated circuit according to a third aspect of the present invention, the integrated circuit according to the first or second aspect of the present invention may further include: a circuit unit configured to amplify a high-frequency signal supplied to an antenna element; and a power detection circuit configured to compare a voltage output obtained by detecting power of the high-frequency signal amplified by the circuit unit with a predetermined reference voltage, and outputs a power detection signal having a first level in a case where the voltage output is higher than the reference voltage and outputs the power detection signal having a second level in a case where the voltage output is lower than the reference voltage. The abnormality detection circuit may detect presence or absence of an abnormality in the high-frequency signal based on an amplification factor setting value that defines an amplification factor of the circuit unit and the power detection signal output from the power detection circuit.

According to an integrated circuit according to a fourth aspect of the present invention, in the integrated circuit according to the third aspect of the present invention, the abnormality detection circuit may detect a first abnormality in a case where the amplification factor setting value is larger than a first setting reference value and the power detection signal is at the second level, and may detect a second abnormality in a case where the amplification factor setting value is smaller than a second setting reference value that is smaller than the first setting reference value and the power detection signal is at the first level.

According to an integrated circuit according to a fifth aspect of the present invention, in the integrated circuit according to the fourth aspect of the present invention, the abnormality detection circuit may not detect the first abnormality and the second abnormality in a case where the amplification factor setting value is smaller than the first setting reference value and larger than the second setting reference value.

According to an integrated circuit according to a sixth aspect of the present invention, in the integrated circuit according to the fourth or fifth aspect of the present invention, the reference voltage may be set such that a level of the power detection signal is switched in a case where the amplification factor setting value is a value between the first setting reference value and the second setting reference value.

According to an integrated circuit according to a seventh aspect of the present invention, in the integrated circuit according to any one of the first to sixth aspects of the present invention, the abnormality detection circuit may be a circuit that detects a communication telegram protocol abnormality in a case where a content of a received communication telegram is an invalid instruction.

According to an abnormality history management method according to one aspect of the present invention, in a case where the detection result of the abnormality detection circuit provided in an integrated circuit indicates an abnormality, the integrated circuit performs: a first step of storing a detection result of an abnormality detection circuit as first information, the first information indicating a latest detection result of the abnormality detection circuit, in a first storage region that stores the first information; and a second step of storing the detection result of the abnormality detection circuit as second information, the second information indicating a detection history of the abnormality detected by the abnormality detection circuit, in a second storage region that is provided corresponding to the first storage region and stores the second information, and in a case where the detection result of the abnormality detection circuit does not indicate an abnormality, the integrated circuit performs only the first step and not the second step.

According to the present invention, there is an effect that it is possible to know the occurrence of an abnormal state and whether or not the abnormal state is continuing.

### BRIEF DESCRIPTION OF THE DRAWINGS

FIG. 1 is a system configuration diagram showing the configuration of a wireless communication device in an embodiment of the present invention.

FIG. 2 is a block diagram showing a main configuration of a beamformer integrated circuit according to the embodiment of the present invention.

FIG. 3 is a block diagram showing the configuration of a power detection circuit provided in the wireless communication device according to the embodiment of the present invention.

FIG. 4 is a diagram showing a connection relationship between a digital circuit unit and an analog circuit unit provided in an RF front end of the beamformer integrated circuit according to the embodiment of the present invention.

FIG. 5 is a diagram showing a configuration example of an abnormality detection system that detects an output power abnormality by using a power detection signal output from a power detection circuit in the embodiment of the present invention.

FIG. 6 is a diagram showing another configuration example of the abnormality detection system that detects the output power abnormality by using the power detection signal output from the power detection circuit in the embodiment of the present invention.

FIG. 7 is a block diagram showing a configuration example of an abnormality detection system that detects a protocol abnormality of the beamformer integrated circuit according to the embodiment of the present invention.

FIG. 8 is a diagram showing an example of a memory map of registers provided in a beamformer integrated circuit according to the embodiment of the present invention.

### DETAILED DESCRIPTION OF THE INVENTION

Hereinafter, an integrated circuit and an abnormality history management method according to an embodiment of the present invention will be described in detail with reference to the drawings. In the following, a beamformer integrated circuit will be described as an example of the integrated circuit according to the embodiment of the present invention. In addition, a phased array antenna module and a wireless communication device including the beamformer integrated circuit will also be described.

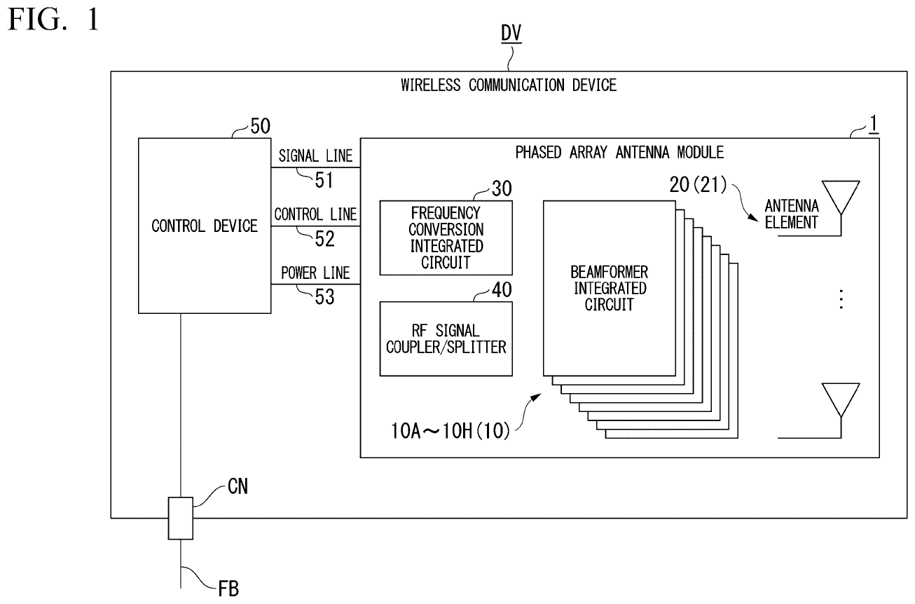

FIG. 1 is a system configuration diagram showing the configuration of a wireless communication device in an embodiment of the present invention. As shown in FIG. 1, the wireless communication device DV of the present embodiment includes a phased array antenna module 1 and a control device 50. The wireless communication device DV can perform beam forming that can freely change a beam pattern, for example, by using a millimeter wave band.

The phased array antenna module 1 has, for example, a plurality of integrated circuits (IC) mounted on one surface of a board such as a printed board in the related art, and an antenna array mounted on the other surface. The plurality of integrated circuits and the antenna array that constitute the phased array antenna module 1 are formed by using a material in the related art and by using a method in the related art. In addition, an electrical connection structure between the plurality of integrated circuits and an electrical connection structure between an integrated circuit and the antenna array are not particularly limited. As the electrical connection structure, a connection structure in the related art is adopted.

The control device 50 communicates with, for example, an upper-level device (not shown) installed at a base portion of a pole or a tower or in a telecommunications facility building via an optical fiber FB, and communicates with a facing wireless communication device such as a mobile terminal or a fixed wireless access network facility, a base station facility, or the like by using the phased array antenna module 1. The control device 50 includes an optical transceiver (not shown) or a pluggable type optical transceiver with an optical connector. The optical fiber FB is connected to an optical transceiver of the control device 50 via an optical connector CN installed in a housing of the wireless communication device DV.

### <Phased Array Antenna Module>

As shown in FIG. 1, the phased array antenna module 1 includes eight beamformer integrated circuits 10A, 10B, 10C, 10D, 10E, 10F, 10G, and 10H (hereinafter, referred to as beamformer integrated circuits 10A to 10H), an antenna array 20, a frequency conversion integrated circuit 30, and an RF signal coupler/splitter 40.

The phased array antenna module 1 is connected to a control device 50 via a signal line 51, a control line 52, and a power line 53. Transmission and reception of an RF signal having a signal frequency of an intermediate frequency (IF) are performed between the control device 50 and the phased array antenna module 1 via the signal line 51. Transmission and reception of a communication telegram related to the control via the control line 52 are performed between the control device 50 and the phased array antenna module 1. Power is supplied from the control device 50 to the phased array antenna module 1 via the power line 53.

The beamformer integrated circuits 10A to 10H are integrated circuits that control a beam pattern of the antenna array 20. A plurality of antenna elements 21 constituting the antenna array 20 are connected to each of the beamformer integrated circuits 10A to 10H. For example, eight antenna elements 21 for horizontal polarization and eight antenna elements 21 for vertical polarization are connected to each of the beamformer integrated circuits 10A to 10H. That is, the antenna array 20 is configured with a total of the 128 antenna elements 21, which are the 64 antenna elements 21 for horizontal polarization and the 64 antenna elements 21 for vertical polarization. The details of the beamformer integrated circuits 10A to 10H will be described below.

The frequency conversion integrated circuit 30 is an integrated circuit that performs frequency conversion between an RF signal of an IF signal frequency and an RF signal of a frequency transmitted and received by the beamformer integrated circuits 10A to 10H and the antenna array 20.

The RF signal coupler/splitter 40 distributes the RF signal output from the frequency conversion integrated circuit 30 to each of the beamformer integrated circuits 10A to 10H. In addition, the RF signal coupler/splitter 40 couples the RF signals received by the respective beamformer integrated circuits 10A to 10H and inputs the coupled RF signals to the frequency conversion integrated circuit 30.

### <Beamformer Integrated Circuit>

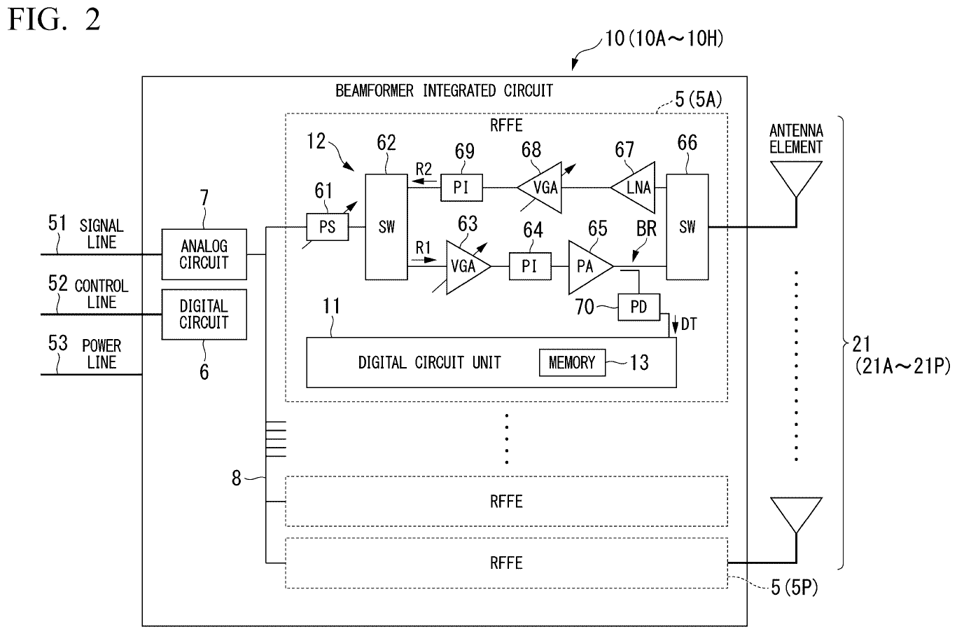

FIG. 2 is a block diagram showing a main configuration of a beamformer integrated circuit according to the embodiment of the present invention. The eight beamformer integrated circuits 10A to 10H have the same configuration. Therefore, in the following description, one of the beamformer integrated circuits 10A to 10H, that is, the beamformer integrated circuit 10 may be described. The description of the other seven beamformer integrated circuits may be omitted.

The beamformer integrated circuit 10 (integrated circuit) includes 16 RF front ends (RFFE) 5A to 5P, a digital circuit 6, an analog circuit 7, and an RF signal coupler/splitter 8. The 16 RF front ends 5A to 5P have the same configuration as each other. Therefore, in the following description, there is a case where one of the 16 RF front ends 5A to 5P, that is, an RF front end 5 will be described. The description of the other 15 RF front ends may be omitted.

In the one beamformer integrated circuit 10 shown in FIG. 2, each of the 16 RF front ends 5A to 5P is connected to each of 16 antenna elements 21A to 21P such that the one antenna element 21 corresponds to the one RF front end 5 on a one-to-one basis. Among the 16 RF front ends 5A to 5P and the 16 antenna elements 21A to 21P, eight RF front ends (for example, RF front ends 5A to 5H) and eight antenna elements (for example, antenna elements 21A to 21H) are for horizontal polarization, and the remaining eight RF front ends (for example, RF front ends 5I to 5P) and eight antenna elements (for example, antenna elements 211 to 21P) are for vertical polarization.

The 16 antenna elements 21A to 21P have the same configuration or a similar configuration to each other. Therefore, in the following description, one of the 16 antenna elements 21A to 21P, that is, the antenna element 21 may be described. The description of the other 15 antenna elements may be omitted. The antenna elements 21A to 21P may have the same configuration as each other. Regarding the configuration of each of the antenna elements 21A to 21P, the configuration of the antenna element for horizontal polarization and the configuration of the antenna element for vertical polarization may be slightly different.

In this way, in the one beamformer integrated circuit 10, each of the 16 RF front ends 5A to 5P is connected to each of the 16 antenna elements 21A to 21P on a one-to-one basis. Therefore, in the entire phased array antenna module 1 having the eight beamformer integrated circuits 10A to 10H, each of the 128 antenna elements 21 constituting the antenna array 20 is connected to each of the 16 RF front ends 5A to 5P in each of the eight beamformer integrated circuits 10A to 10H.

The 128 antenna elements 21 constituting the antenna array 20 are divided into the 64 antenna elements 21 that transmit and receive radio waves of horizontal polarization and the 64 antenna elements 21 that transmit and receive radio waves of vertical polarization. The eight beamformer integrated circuits 10A to 10H control transmission and reception of the radio waves of horizontal polarization in the 64 antenna elements 21, and control transmission and reception of the radio waves of vertical polarization in the 64 antenna elements 21. Regarding each of the radio waves of horizontal polarization and the radio waves of vertical polarization, the beamformer integrated circuits 10A to 10H set the phases and intensities of the 64 antenna elements such that the direction of the combined radio wave transmitted or received from the 64 antenna elements 21 is a predetermined direction.

As shown in FIG. 2, the RF front end 5 includes a digital circuit unit 11 and an analog circuit unit 12 (circuit unit). The digital circuit unit 11 transmits and receives communication telegrams related to the control to and from the control device 50 via the control line 52 shown in FIG. 1. The digital circuit unit 11 controls the RF front end 5 based on the communication telegram transmitted from the control device 50.

In the present embodiment, the transmission and reception of communication telegram related to the control are performed by the parallel communication between the phased array antenna module 1 and the control device 50. That is, the digital circuit unit 11 transmits and receives the communication telegram related to the control by parallel communication with the control device 50. The communication performed between the phased array antenna module 1 and the control device 50 is not limited to the parallel communication. The communication may be serial communication such as serial peripheral interface (SPI) or inter-integrated circuit (I2C).

The digital circuit unit 11 is connected to the digital circuit 6 by a wiring line inside the beamformer integrated circuit 10. The digital circuit 6 relays the communication performed between the digital circuit unit 11 and the control device 50. Alternatively, the digital circuit 6 communicates with the digital circuit unit 11 based on the content of the communication telegram transmitted from the control device 50.

One communication transaction transmitted from the control device 50 to the phased array antenna module 1 includes additional information, a command, and data. The communication transaction has a fixed bit length. The command is a register address used when instructing to write into or read from the register. Alternatively, the command is a numerical value meaning an operation instruction to the beamformer integrated circuit 10 or the RF front end 5. The command or data has a fixed length. In the present embodiment, the command is 8 bits and the data is 16 bits.

The digital circuit unit 11 includes a memory 13 that is a storage region for storing a beam table used for beam forming. The beam table is a look-up table that stores a plurality of combinations of phase shift amount setting values and intensity setting values that are set according to the beam pattern of the antenna array 20 to be controlled. In the present embodiment, a beam table (beam table of 2048 items) in which 2048 combinations of the phase shift amount setting values and the intensity setting values are defined is stored in the memory 13.

The memory 13 is realized by using, for example, a static random-access memory (SRAM). The memory 13 is preferably realized using the SRAM, but may be realized using a register or may be realized using a dynamic random-access memory (DRAM), a flash memory, or a read-only memory (ROM).

The analog circuit unit 12 is a circuit that outputs an RF signal to the antenna element 21 connected to the RF front end 5 or receives an RF signal output from the antenna element 21. The analog circuit unit 12 adjusts the phase and the intensity of the RF signal transmitted and received by the antenna element 21 connected to the RF front end 5 under the control of the digital circuit unit 11.

The analog circuit unit 12 is connected to the analog circuit 7 via the RF signal coupler/splitter 8. The RF signal coupler/splitter 8 distributes the RF signal output from the analog circuit 7 to the analog circuit unit 12 provided in each of the RF front ends 5A to 5P. In addition, the RF signal coupler/splitter 8 couples the RF signals output from the analog circuit unit 12 provided in each of the RF front ends 5A to 5P and outputs the RF signals to the analog circuit 7.

As shown in FIG. 2, the analog circuit unit 12 includes a phase shifter (PS) 61, a path selection switch (SW) 62, a variable gain amplifier (VGA) 63, a phase inverter (PI) 64, a power amplifier (PA) 65, a path selection switch (SW) 66, a low noise amplifier (LNA) 67, a variable gain amplifier (VGA) 68, a phase inverter (PI) 69, and a power detection circuit (PD) 70.

The variable gain amplifier 63, the phase inverter 64, and the power amplifier 65 are provided on a transmission path R1, and the low noise amplifier 67, the variable gain amplifier 68, and the phase inverter 69 are provided on a reception path R2. The transmission path R1 is a path through which the RF signal (high-frequency signal) output to the antenna element 21 passes, and the reception path R2 is a path through which the RF signal (high-frequency signal) input from the antenna element 21 passes. The path selection switches 62 and 66 switch the connection between the phase shifter 61 and the antenna element 21 between the transmission path R1 and the reception path R2 at a defined time interval. Accordingly, the phased array antenna module 1 can transmit and receive a high-frequency signal as a time division multiplexing system.

The phase shifter 61 adjusts the phase shift amount of the RF signal passing through the transmission path R1 or the RF signal passing through the reception path R2 according to the phase shift amount setting value of the beam table read out from the memory 13 of the digital circuit unit 11. That is, the phase shifter 61 is provided in common for the transmission path R1 and the reception path R2. A configuration may be adopted in which the phase shifter 61 common to the transmission path R1 and the reception path R2 is omitted and a phase shifter is individually provided in each of the transmission path R1 and the reception path R2.

The variable gain amplifier 63 amplifies the RF signal passing through the transmission path R1 according to the intensity setting value of the beam table read out from the memory 13. The phase inverter 64 inverts the phase of the RF signal passing through the transmission path R1 according to the phase shift amount setting value of the beam table read out from the memory 13. The power amplifier 65 amplifies the RF signal passing through the transmission path R1 at a predetermined amplification factor. By adjusting the phase shift amount and the intensity of the RF signal passing through the transmission path R1, the beam pattern of the radio wave transmitted from the phased array antenna module 1 can be changed.

The low noise amplifier 67 amplifies the RF signal output from the path selection switch 66 at a predetermined amplification factor. The variable gain amplifier 68 amplifies the RF signal passing through the reception path R2 according to the intensity setting value of the beam table read out from the memory 13. The phase inverter 69 inverts the phase of the RF signal passing through the reception path R2 according to the phase shift amount setting value of the beam table read out from the memory 13. By adjusting the phase shift amount and the intensity of the RF signal passing through the reception path R2, the beam pattern of the radio wave received by the phased array antenna module 1 can be changed.

The power detection circuit 70 detects the power of the RF signal amplified by the power amplifier 65 and supplied to the antenna element 21, and outputs a signal (digital signal) indicating the detection result. Specifically, a branching device BR that branches the RF signal amplified by the power amplifier 65 at a stable branch ratio is provided on the transmission path R1 between the power amplifier 65 and the path selection switch 66. One of the RF signals branched by the branching device BR is supplied to the path selection switch 66, and the other RF signal branched by the branching device BR is supplied to the power detection circuit 70. The power detection circuit 70 detects power by inputting the power of the other RF signal branched by the branching device BR, and outputs a signal (digital signal) indicating the detection result.

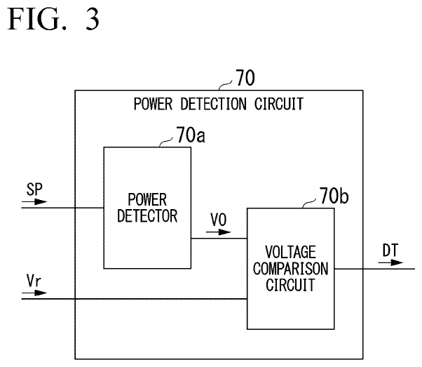

FIG. 3 is a block diagram showing a configuration of the power detection circuit provided in the wireless communication device in the embodiment of the present invention. As shown in FIG. 3, the power detection circuit 70 includes a power detector 70a and a voltage comparison circuit 70b. The power detector 70a detects the power of the other RF signal SP branched by the branching device BR shown in FIG. 2, and outputs the detection result as a voltage output VO.

The voltage output VO is a signal (analog signal) of which the voltage changes according to the detection result of the power of the RF signal SP. For example, the voltage output VO may be a signal in which the height of the voltage changes in proportion to the magnitude of the detected power.

The voltage comparison circuit 70b compares the voltage output VO of the power detector 70a with a predetermined reference voltage Vr, and outputs a power detection signal DT according to the comparison result. The power detection signal DT is a digital signal. Specifically, the voltage comparison circuit 70b outputs the power detection signal DT that is at an “H (high)” level (first level) in a case where the voltage output VO is higher than the reference voltage Vr and is at an “L (low)” level (second level) in a case where the voltage output VO is lower than the reference voltage Vr. The reference voltage Vr will be described below. The power detection signal DT, which is a digital signal, is input to the digital circuit unit 11 in the RF front end 5.

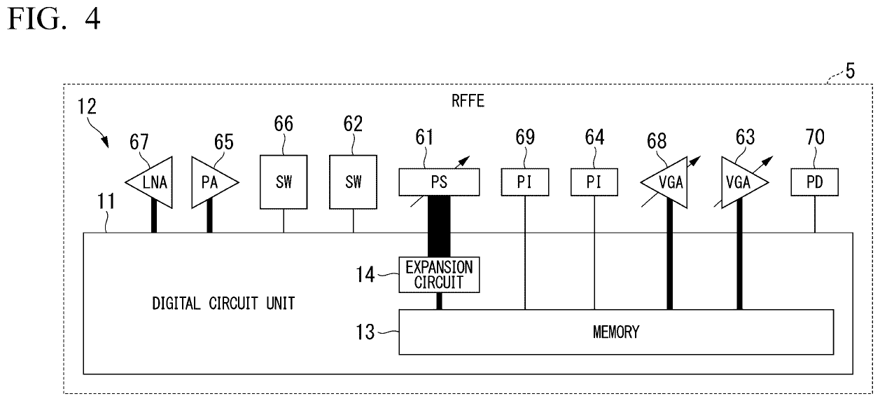

FIG. 4 is a diagram showing a connection relationship between the digital circuit unit and the analog circuit unit provided in the RF front end of the beamformer integrated circuit according to the embodiment of the present invention. As shown in FIG. 4, the phase shifter 61, the variable gain amplifiers 63 and 68, and the phase inverters 64 and 69 provided in the analog circuit unit 12 are controlled in accordance with the contents of the beam table stored in the memory 13. In contrast, the path selection switches 62 and 66, the power amplifier 65, and the low noise amplifier 67 provided in the analog circuit unit 12 are controlled by a logic circuit (not shown) such as a register provided in the digital circuit unit 11. The power detection signal DT output from the power detection circuit 70 is input to the digital circuit unit 11.

An expansion circuit 14 expands a bit string of a phase shift amount setting value of the beam table read out from the memory 13 into a bit string of a control value (phase shifter control value) for controlling the phase shifter 61. The phase shift amount setting value stored in the beam table is, for example, 7 bits, and the intensity setting value is, for example, 5 bits. The expansion circuit 14 expands a bit string of 6 bits of the phase shift amount setting value of 7 bits into a bit string of 52 bits of the control value. The remaining one bit of the phase shift amount setting value is used for controlling the phase inverters 64 and 69. The number of bits of the phase shift amount setting value is set according to the resolution of the phase shift amount, and the number of bits of the control value is set according to the number of divided units constituting the phase shifter 61.

In a case where the most significant bit of the phase shift amount setting value is “1”, the phase inverter 64 or 69 is instructed to perform phase inversion. This corresponds to setting the phase shift amount of 180 degrees. The lower 6 bits of the phase shift amount setting value are used to indicate a divided unit of the 52 divided units constituting the phase shifter 61, of which the state is to be changed. In the 52 divided units constituting the phase shifter 61, in a case where the value of the lower 6 bits of the phase shift amount setting value is “0”, all of the 52 divided units are in a reference state, and in a case where the value is “1” to “52”, the divided unit(s) for the value is (are) set to the phase shift state. In a case where the value of the lower 6 bits of the phase shift amount setting value is “52”, all of the 52 divided units constituting the phase shifter 61 are set to the phase shift state. That is, in a case where the phase shifter 61 is constituted by 52 divided units, the phase shift state of the phase shifter 61 can be set to 53 stages.

The phase shifter 61 is designed such that a phase shift amount in a case where all of the 52 divided units are set to the phase shift state exceeds 180 degrees in a frequency range used in the phased array antenna module 1. In the present embodiment, the configuration in which the phase shift amount of the RF signal passing through the transmission path R1 or the reception path R2 is adjusted by the combination of the phase inverters 64 and 69 and the phase shifter 61 capable of setting the phase shift amount of more than 180 degrees has been described as an example, but the present invention is not limited to this configuration. A configuration may be adopted in which only a phase shifter capable of setting the phase shift amount of more than 360 degrees is used without using the phase inverters 64 and 69.

As described above, the lower 6 bits of the phase shift amount setting value are expanded into a bit string (52 bits) of a control value (phase shifter control value) for controlling the phase shifter 61 by the expansion circuit 14 shown in FIG. 4. That is, the lower 6 bits of the phase shift amount setting value are expanded into a bit string having the same number of bits as the number of divided units constituting the phase shifter 61. The number of divided units constituting the phase shifter 61 is not limited to 52 and may be any number.

The 5 bits of the intensity setting value are gain setting values that define the gain settings of the variable gain amplifiers 63 and 68. By individually setting the intensity setting values of 5 bits in the variable gain amplifiers 63 and 68, the signal intensity of the RF signal passing through the transmission path R1 and the RF signal passing through the reception path R2 are individually adjusted.

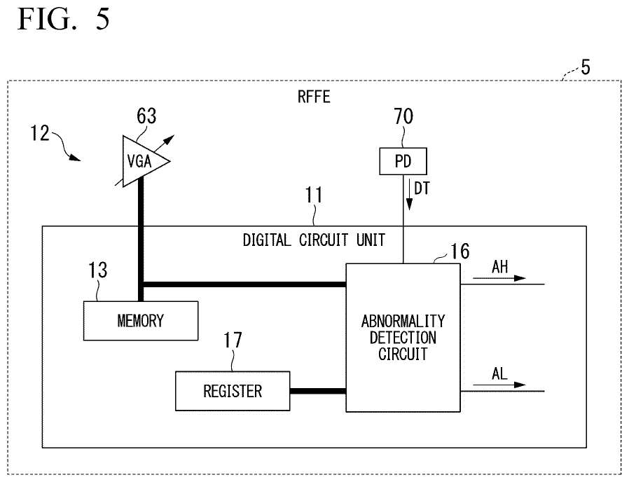

FIG. 5 is a diagram showing a configuration example of an abnormality detection system that detects an output power abnormality by using the power detection signal output from the power detection circuit in the embodiment of the present invention. The abnormality detection system shown in FIG. 5 includes a memory 13, a register 17, and an abnormality detection circuit 16 provided in the digital circuit unit 11.

As described above, the memory 13 stores a beam table including the gain setting value that defines the gain setting of the variable gain amplifier 63. The gain setting (amplification factor of the circuit unit) of the RF signal passing through the transmission path R1 of the analog circuit unit 12 is defined by the gain setting value read out from the memory 13 and the gain setting value set for the power amplifier 65. Hereinafter, the gain setting value that defines the gain setting of the RF signal passing through the transmission path R1 of the analog circuit unit 12 is referred to as a “transmission signal gain setting value”.

The register 17 stores a high output setting reference value RH (first setting reference value) and a low output setting reference value RL (second setting reference value) used in a case where the presence or absence of an abnormality in the output power of the power amplifier 65 is detected. The high output setting reference value RH and the low output setting reference value RL are reference values set with respect to the transmission signal gain setting value. The high output setting reference value RH and the low output setting reference value RL held in the register 17 can be rewritten based on an instruction from the control device 50.

Specifically, the high output setting reference value RH is a reference value for determining whether or not the transmission signal gain setting value causes the output power of the power amplifier 65 to be greater than a predetermined first power (to be a high output). The low output setting reference value RL is a reference value for determining whether or not the transmission signal gain setting value causes the output power of the power amplifier 65 to be a predetermined second power lower than the first power (to be a low output).

The abnormality detection circuit 16 detects the presence or absence of an abnormality in the RF signal (output power of the power amplifier 65) amplified by the power amplifier 65 and supplied to the antenna element 21 based on the transmission signal gain setting value and the power detection signal DT output from the power detection circuit 70. The abnormality detection circuit 16 uses the high output setting reference value RH and the low output setting reference value RL stored in the register 17 in a case where the presence or absence of the abnormality of the output power of the power amplifier 65 is detected.

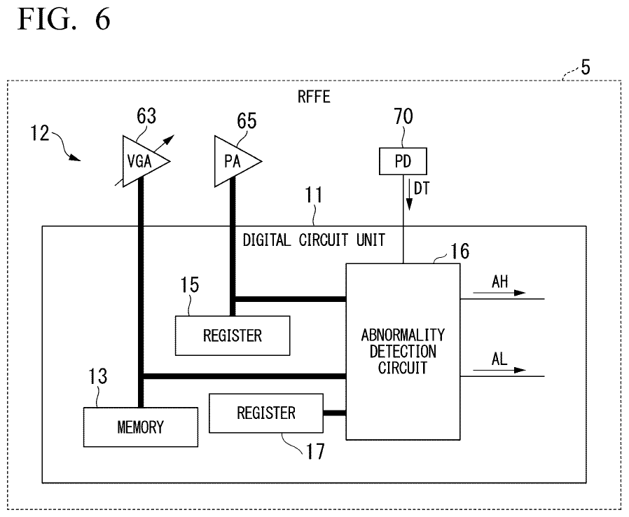

FIG. 6 is a diagram showing another configuration example of the abnormality detection system that detects the output power abnormality by using the power detection signal output from the power detection circuit in the embodiment of the present invention. The abnormality detection system shown in FIG. 6 includes a register 15 provided in the digital circuit unit 11, in addition to the memory 13, the register 17, and the abnormality detection circuit 16 provided in the digital circuit unit 11.

The register 15 holds a gain setting value that defines the gain setting of the power amplifier 65. The gain setting value held in the register 15 can be rewritten based on an instruction from the control device 50. That is, the abnormality detection system shown in FIG. 6 is different from the abnormality detection system shown in FIG. 5 in that the gain setting of the power amplifier 65 can be appropriately changed, and the transmission signal gain setting value is defined by the gain setting value read out from the memory 13 and the gain setting value held in the register 15. The abnormality detection system shown in FIG. 6 is the same as the abnormality detection system shown in FIG. 5 in that the abnormality detection circuit 16 detects the presence or absence of an abnormality in the output power of the power amplifier 65 based on the transmission signal gain setting value and the power detection signal DT.

The high output setting reference value RH and the low output setting reference value RL are set such that the high output setting reference value RH is larger than the low output setting reference value RL in a range in which the output power of the power amplifier 65 can be changed. In this case, the reference voltage Vr used in the voltage comparison circuit 70b of the power detection circuit 70 is set such that the level of the power detection signal DT is switched in a case where the gain setting value is between the high output setting reference value RH and the low output setting reference value RL.

In a case where the transmission signal gain setting value is larger than the high output setting reference value RH and the power detection signal DT is at the “L” level, the abnormality detection circuit 16 outputs a low output abnormality detection signal AL. That is, in a case where the power detected by the power detection circuit 70 is low even though the transmission signal amplification factor setting value is a value indicating high output, the abnormality detection circuit 16 detects an abnormality (first abnormality) and outputs the low output abnormality detection signal AL at the “H” level.

In a case where the transmission gain factor setting value is smaller than the low output setting reference value RL and the power detection signal DT is at the “H” level, the abnormality detection circuit 16 outputs a high output abnormality detection signal AH (second abnormality signal). That is, in a case where the power detected by the power detection circuit 70 is high even though the transmission signal gain setting value is a value indicating low output, the abnormality detection circuit 16 detects an abnormality (second abnormality) and outputs the high output abnormality detection signal AH at the “H” level.

In a case where the transmission signal gain setting value is smaller than the high output setting reference value RH and larger than the low output setting reference value RL, the abnormality detection circuit 16 does not output the low output abnormality detection signal AL and the high output abnormality detection signal AH regardless of the level of the power detection signal DT. That is, the abnormality detection circuit 16 does not detect the abnormality of the output power because the transmission signal gain setting value is a value between the value indicating high output and the value indicating low output. That is, the low output abnormality detection signal AL and the high output abnormality detection signal AH are at the “L” level.

In this way, in the abnormality detection circuit 16, the output power abnormality can be detected by a flexible determination criterion according to the content (the gain setting value that defines the gain setting of the variable gain amplifier 63) of the beam table, or the content (the gain setting value that defines the gain setting of the power amplifier 65) of the beam table and the content of the register 15. Moreover, since the power detection signal DT, which is the digital signal output from the power detection circuit 70, is used for detecting the output power abnormality, the output power abnormality can be detected with high real-time performance.

The high output abnormality detection signal AH and the low output abnormality detection signal AL output from the abnormality detection circuit 16 are acquired by the control device 50. The high output abnormality detection signal AH and the low output abnormality detection signal AL output from the abnormality detection circuit 16 may be stored in a register (not shown) provided in the digital circuit unit 11. Then, the control device 50 may issue an acquisition request to the digital circuit unit 11 to acquire the high output abnormality detection signal AH and the low output abnormality detection signal AL stored in the register.

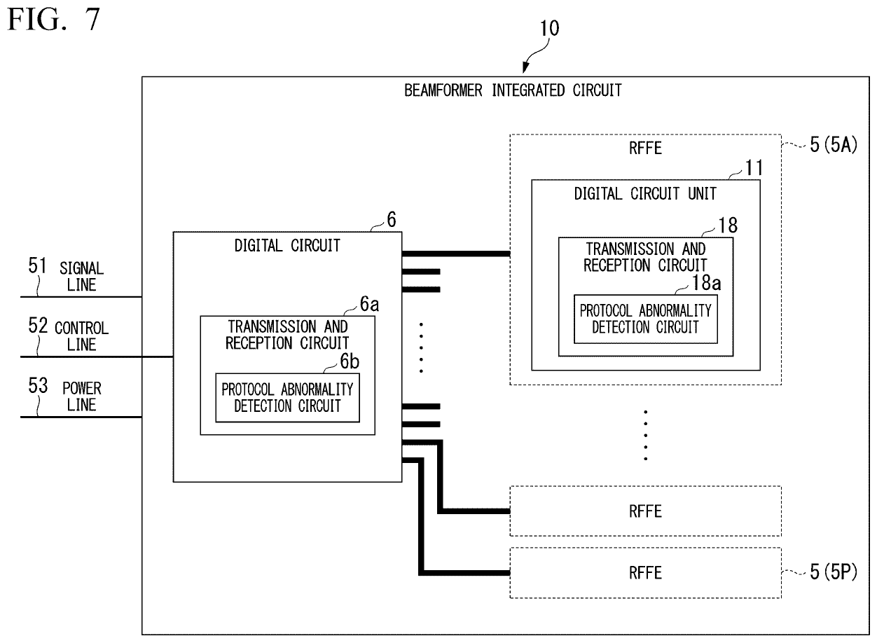

FIG. 7 is a block diagram showing a configuration example of an abnormality detection system that detects a protocol abnormality of the beamformer integrated circuit according to the embodiment of the present invention. As shown in FIG. 7, a transmission and reception circuit 18 is provided in the digital circuit unit 11 of each of the RF front ends 5A to 5P, and a transmission and reception circuit 6a is provided in the digital circuit 6. In addition, a protocol abnormality detection circuit 18a (abnormality detection circuit) that detects a communication protocol error (communication telegram protocol abnormality) is provided in each of the transmission and reception circuits 18, and a protocol abnormality detection circuit 6b (abnormality detection circuit) that detects a communication protocol error is provided in the transmission and reception circuit 6a.

The transmission and reception circuit 6a provided in the digital circuit 6 receives the communication telegram transmitted from the control device 50 and analyzes the content thereof. The protocol abnormality detection circuit 6b provided in the transmission and reception circuit 6a detects the presence or absence of a communication protocol error. The protocol abnormality detection circuit 6b detects a communication protocol error in a case where the content of the communication telegram received by the transmission and reception circuit 6a is an invalid instruction. The transmission and reception circuit 18 provided in the digital circuit unit 11 of each of the RF front ends 5A to 5P receives the communication telegram transmitted from the control device 50 and analyzes the content thereof. The protocol abnormality detection circuit 18a provided in the transmission and reception circuit 18 detects the presence or absence of a communication protocol error. The protocol abnormality detection circuit 18a detects a communication protocol error in a case where the content of the communication telegram received by the transmission and reception circuit 18 is an invalid instruction.

### <Memory Map of Register>

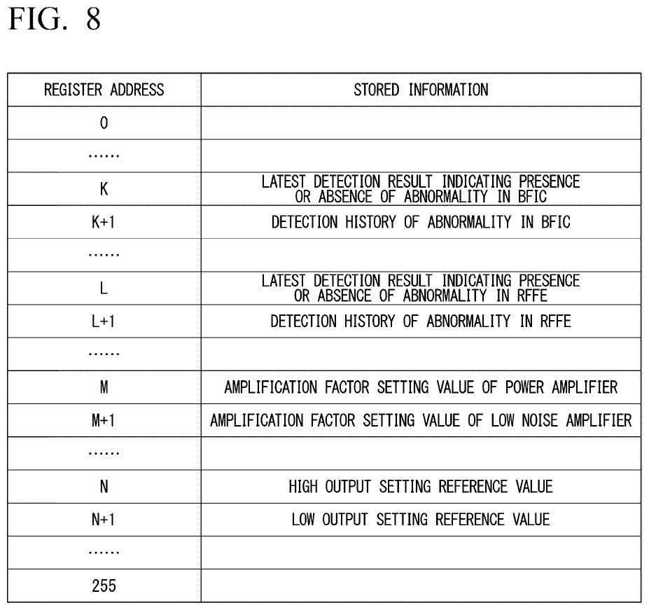

FIG. 8 is a diagram showing an example of a memory map of registers provided in the beamformer integrated circuit according to the embodiment of the present invention. In the present embodiment, the addresses of the memory map of the registers are 8 bits, and a value from “0” to “255” can be specified. In addition, the storage capacity of each register is, for example, a maximum of 16 bits. In the present embodiment, an 8-bit address space is shared by registers provided in the frequency conversion integrated circuit 30, registers provided in the digital circuit 6 of the beamformer integrated circuit 10, and registers provided in the digital circuit unit 11 of the RF front end 5.

The registers are storage areas in which information is stored by specifying an address and performing a write operation, and the stored information can be acquired by specifying an address and performing a read operation. In addition, the information may be stored in the registers or the information stored in the registers may be updated by the digital circuit 6 of the beamformer integrated circuit 10 or the logic circuit provided in the digital circuit unit 11 of the RF front end 5.

In the example shown in FIG. 8, registers to which an address K and an address K+1 are assigned are the registers provided in the digital circuit 6 of the beamformer integrated circuit 10. In addition, registers to which an address L, an address L+1, an address M, an address M+1, an address N, and an address N+1 are assigned are the registers provided in the digital circuit unit 11 of the RF front end 5.

That is, in a case where the write operation or the read operation is instructed by specifying the address K or the address K+1, writing or reading is performed with respect to a register provided in the digital circuit 6 of the beamformer integrated circuit 10. In addition, in a case where the write operation or the read operation is instructed by specifying the address L, the address L+1, the address M, the address M+1, the address N, and the address N+1, writing or reading is performed with respect to the registers provided in the digital circuit unit 11 of the RF front end 5 separately selected in advance. The selection and specification of the RF front end 5 is performed, for example, by using a register (not shown) provided in the digital circuit 6 of the beamformer integrated circuit 10.

Although not shown in FIG. 8, a certain address range is also assigned to the registers provided in the frequency conversion integrated circuit 30. In a case where a write operation or a read operation is instructed by specifying an address within this range, writing or reading is performed with respect to a register provided in the frequency conversion integrated circuit 30.

Information (first information) indicating the latest detection result indicating the presence or absence of an abnormality in the beamformer integrated circuit 10 is stored in the register (first storage region) to which the address K is assigned. In addition, information (second information) indicating a detection history of the abnormality detected by the beamformer integrated circuit 10 is stored in the register (second storage region) to which the address K+1 is assigned.

Information (first information) indicating the latest detection result indicating the presence or absence of an abnormality in the RF front end 5 is stored in a register (first storage region) to which the address L is assigned. In addition, information (second information) indicating a detection history of the abnormality detected by the RF front end 5 is stored in a register (second storage region) to which the address L+1 is assigned.

The gain setting value that defines the gain setting of the power amplifier 65 provided in the RF front end 5 is stored in a register to which the address M is assigned. A gain setting value that defines a gain setting of the low noise amplifier 67 provided in the RF front end 5 is stored in a register to which the address M+1 is assigned. The high output setting reference value RH is stored in a register to which the address N is assigned. The low output setting reference value RL is stored in a register to which the address N+1 is assigned. The register to which the address M is assigned is the register 15 shown in FIG. 6, and the register to which the address N and the address N+1 are assigned is the register 17 shown in FIGS. 5 and 6.

The information stored in the register to which the address K is assigned and the register to which the address K+1 is assigned is composed of a plurality of bits. For example, the information is composed of a bit (hereinafter, referred to as an “RFFE abnormality detection bit”) indicating whether or not an abnormality is detected in the RF front end 5, a bit (hereinafter, referred to as a “first communication error detection bit”) indicating whether or not a communication protocol error is detected in the digital circuit 6, and the like. The information stored in the register to which the address K is assigned and the register to which the address K+1 is assigned is updated in units of bits according to the abnormality detected by the beamformer integrated circuit 10.

The information stored in the register to which the address L is assigned and the register to which the address L+1 is assigned also is composed of a plurality of bits. For example, the information is composed of a bit indicating whether or not an abnormality is detected in the RF front end 5, a bit (hereinafter, referred to as a “high output abnormality detection bit”) indicating whether or not a high output abnormality is detected, a bit (hereinafter, referred to as a “low output abnormality detection bit”) indicating whether or not a low output abnormality is detected, a bit (hereinafter, referred to as a “second communication error detection bit”) indicating whether or not a communication protocol error is detected in the digital circuit unit 11 of the RF front end 5, and the like. The information stored in the register to which the address L is assigned and the register to which the address L+1 is assigned is updated in units of bits according to the abnormality detected by the RF front end 5.

In a case where an address is specified and a communication telegram instructing to read out information stored in a register to which the address is assigned is received, the beamformer integrated circuit 10 reads out the information stored in a register to which the address is assigned. Then, the beamformer integrated circuit 10 transmits a communication telegram including the readout information. For example, in a case where a communication telegram of a readout instruction is transmitted from the control device 50, a communication telegram including the readout information is transmitted to the control device 50.

### <Abnormality History Management Method>

Next, an operation in a case where the presence or absence of an abnormality is detected in the digital circuit 6 of the beamformer integrated circuit 10 or the digital circuit unit 11 of the RF front end 5 will be described. In the following, first, in the digital circuit unit 11 of the RF front end 5, an operation (an operation when an output abnormality is detected) in a case where the presence or absence of an output abnormality of the power amplifier 65 is detected will be described. Next, an operation (an operation when a communication error is detected) in a case where the presence or absence of a communication protocol error is detected in the digital circuit 6 or the digital circuit unit 11 of the RF front end 5 will be described. Subsequently, an operation (reset operation) in a case where the storage content of the register is deleted will be described.

<<Operation when Output Abnormality is Detected>>

In the abnormality detection system shown in FIG. 5 or FIG. 6, in a case where a high output abnormality of the output power of the power amplifier 65 is detected, the high output abnormality detection signal AH is output from the abnormality detection circuit 16 of the abnormality detection system. Then, for example, the value of the high output abnormality detection bit is set to, for example, “1” in the register to which the address L is assigned, by the logic circuit provided in the digital circuit unit 11 of the RF front end 5 (first step). In addition, in the register to which the address L+1 is assigned, the value of the high output abnormality detection bit is also set to, for example, “1” (second step).

In a case where the high output abnormality is not detected, only the value of the high output abnormality detection bit in the register to which the address L is assigned is set to, for example, “0” (first step). The value is held for the high output abnormality detection bit in the register to which the address L+1 is assigned. That is, the step (second step) of setting the value of the high output abnormality detection bit to “0” in the register to which the address L+1 is assigned is not performed.

In the abnormality detection system shown in FIG. 5 or FIG. 6, in a case where a low output abnormality of the output power of the power amplifier 65 is detected, the low output abnormality detection signal AL is output from the abnormality detection circuit 16 of the abnormality detection system. Then, for example, the value of the low output abnormality detection bit is set to, for example, “1” in the register to which the address L is assigned, by the logic circuit provided in the digital circuit unit 11 of the RF front end 5 (first step). In addition, in the register to which the address L+1 is assigned, the value of the low output abnormality detection bit is also set to, for example, “1” (second step).

In a case where the low output abnormality is not detected, only the value of the low output abnormality detection bit in the register to which the address L is assigned is set to, for example, “0” (first step). The value is held for the low output abnormality detection bit in the register to which the address L+1 is assigned. That is, the step (second step) of setting the value of the low output abnormality detection bit to “0” in the register to which the address L+1 is assigned is not performed.

<<Operation when Communication Error is Detected>>

It is assumed that a communication protocol error is detected in the protocol abnormality detection circuit 6b of the abnormality detection system shown in FIG. 7. Then, for example, the value of the first communication error detection bit is set to, for example, “1” in the register to which the address K is assigned, by the logic circuit provided in the digital circuit 6 (first step). In addition, in the register to which the address K+1 is assigned, the value of the first communication error detection bit is also set to, for example, “1” (second step).

In a case where the communication protocol error is not detected in the protocol abnormality detection circuit 6b, only the value of the first communication error detection bit in the register to which the address K is assigned is set to, for example, “0” (first step). The value is held for the first communication error detection bit in the register to which the address K+1 is assigned. That is, the step (second step) of setting the value of the first communication error detection bit to “0” in the register to which the address K+1 is assigned is not performed.

It is assumed that a communication protocol error is detected in the protocol abnormality detection circuit 18a of the abnormality detection system shown in FIG. 7. Then, for example, the value of the second communication error detection bit is set to, for example, “1” in the register to which the address L is assigned, by the logic circuit provided in the digital circuit unit 11 of the RF front end 5 (first step). In addition, in the register to which the address L+1 is assigned, the value of the second communication error detection bit is also set to, for example, “1” (second step).

In a case where the communication protocol error is not detected by the protocol abnormality detection circuit 18b, only the value of the second communication error detection bit in the register to which the address L is assigned is set to, for example, “0” (first step). The value is held for the second communication error detection bit in the register to which the address L+1 is assigned. That is, the step (second step) of setting the value of the second communication error detection bit to “0” in the register to which the address L+1 is assigned is not performed.

Here, in a case where the value of any bit in the register to which the address L is assigned is “1”, the value of the RFFE abnormality detection bit is set to, for example, “1” in the register to which the address K is assigned and the register to which the address K+1 is assigned. The case where the value of any bit in the register to which the address L is assigned is “1” is a case where the value of the information stored in the register to which the address L is assigned is not “0”.

In contrast, in a case where the values of all bits in the register to which the address L is assigned are “0”, only the value of the RFFE abnormality detection bit in the register to which the address K is assigned is set to, for example, “0”. The value is held for the RFFE abnormality detection bit in the register to which the address K+1 is assigned. The case where the value of all bits in the register to which the address L is assigned is “0” is a case where the value of the information stored in the register to which the address L is assigned is “0”.

In this way, in the register to which the address K+1 is assigned, the information indicating the detection history of the abnormality detected by the beamformer integrated circuit 10 is stored by using a plurality of bits, and in a case where there is the detection history, the value of the corresponding bit is, for example, “1”. In a case where an abnormality is detected in any RF front end 5, the values of specific bits of both the register to which the address L+1 is assigned and the register to which the address K+1 is assigned are “1”. Accordingly, it is possible to determine the presence or absence of the detection history of the abnormality detected by the beamformer integrated circuit 10 by referring only to the register to which the address K+1 is assigned.

### <<Reset Operation>>

The value stored in the register to which the address K+1 is assigned is set to “0” (reset) during the initialization operation of the register or in a case where the digital circuit 6 of the beamformer integrated circuit 10 receives a communication telegram instructing to delete the contents by specifying the address K+1. Similarly, the value stored in the register to which the address L+1 is assigned is set to “0” (reset) during the initialization operation of the register or in a case where the digital circuit 6 of the beamformer integrated circuit 10 specifies the address L+1 and receives a communication telegram indicating that the contents are to be deleted.

Setting the value stored in the register to which the address K+1 is assigned and the value stored in the register to which the address L+1 is assigned to “0” means that a state where there is no detection history of the abnormality detected in the past is set. In this way, the state where there is no detection history of the abnormality detected in the past is set during the initialization operation of the register or when a communication telegram indicating the deleting of the history is received. Therefore, for example, in a case where the wireless communication device DV is continuously operated, the acquisition of the detection history of the abnormality and the deleting of the acquired detection history can be appropriately repeated.

As described above, in the present embodiment, the abnormality detection circuit 16 that detects the abnormality of the output power of the power amplifier 65 and the protocol abnormality detection circuits 6b and 18a that detect a communication protocol error are provided. Then, the information indicating the detection history of the abnormality detected by the abnormality detection circuits is stored in the register to which the address K+1 is assigned or the register to which the address L+1 is assigned. Accordingly, it is possible to know the occurrence of an abnormal state and to know the occurrence history of an abnormality.

In addition, in the present embodiment, in a case where the latest detection result of the abnormality detection circuit indicates an abnormality, the latest detection result of the abnormality detection circuit is stored in the register to which the address K is assigned or the register to which the address L is assigned. In contrast, in a case where the latest detection result of the abnormality detection circuit does not indicate an abnormality, the latest detection result of the abnormality detection circuit is stored in the register to which the address K is assigned or the register to which the address L is assigned. As a result, it is possible to know the occurrence of the abnormal state and whether or not the abnormal state is continuing.

Although the integrated circuit and the abnormality history management method according to the embodiment of the present invention have been described above, the present invention is not limited to the above-described embodiment and can be freely modified within the scope of the present invention. That is, additions, omissions, substitutions, and other modifications can be made without departing from the scope of the invention. Accordingly, the invention is not to be considered as being limited by the foregoing description and is only limited by the scope of the appended claims.

For example, the above-described power detection signal DT is a signal having the “H” level in a case where the voltage output VO is higher than the reference voltage Vr and the “L (low)” level in a case where the voltage output VO is lower than the reference voltage Vr, but the signal levels may be reversed. The same applies to other digital signals.

In addition, the phased array antenna module described in the above embodiment is for a time division multiplexing system. However, the phased array antenna module of the present invention may be for a frequency division multiplexing system.

In addition, in the above-described embodiment, an example has been described in which the one antenna element 21 is connected to the one RF front end 5 on a one-to-one correspondence. However, in the present invention, two front ends may be connected to a dual polarization antenna element having a connection terminal for horizontal polarization and a connection terminal for vertical polarization.

What is claimed is:

1. An integrated circuit comprising:
an abnormality detection circuit configured to detect presence or absence of an abnormality;
a first storage region configured to store first information indicating a latest detection result of the abnormality detection circuit; and
a second storage region configured to be provided corresponding to the first storage region and stores second information indicating a detection history of the abnormality detected by the abnormality detection circuit.

2. The integrated circuit according to claim 1,
wherein the second information stored in the second storage region is deleted during an initialization operation of a storage region including the second storage region or in a case where a communication telegram for specifying an address of the second storage region and instructing to delete the second information is received.

3. The integrated circuit according to claim 1, further comprising:
a circuit unit configured to amplify a high-frequency signal supplied to an antenna element; and
a power detection circuit configured to compare a voltage output obtained by detecting power of the high-frequency signal amplified by the circuit unit with a predetermined reference voltage, and outputs a power detection signal having a first level in a case where the voltage output is higher than the reference voltage and outputs the power detection signal having a second level in a case where the voltage output is lower than the reference voltage,
wherein the abnormality detection circuit detects presence or absence of an abnormality in the high-frequency signal based on an amplification factor setting value that defines an amplification factor of the circuit unit and the power detection signal output from the power detection circuit.

4. The integrated circuit according to claim 3,
wherein the abnormality detection circuit
detects a first abnormality in a case where the amplification factor setting value is larger than a first setting reference value and the power detection signal is at the second level, and
detects a second abnormality in a case where the amplification factor setting value is smaller than a second setting reference value that is smaller than the first setting reference value and the power detection signal is at the first level.

5. The integrated circuit according to claim 4,
wherein the abnormality detection circuit does not detect the first abnormality and the second abnormality in a case where the amplification factor setting value is smaller than the first setting reference value and is larger than the second setting reference value.

6. The integrated circuit according to claim 4,
wherein the reference voltage is set such that a level of the power detection signal is switched in a case where the amplification factor setting value is a value between the first setting reference value and the second setting reference value.

7. The integrated circuit according to claim 1,
wherein the abnormality detection circuit is a circuit that detects a communication telegram protocol abnormality in a case where a content of a received communication telegram is an invalid instruction.

8. An abnormality history management method,
wherein in a case where the detection result of the abnormality detection circuit provided in an integrated circuit indicates an abnormality, the integrated circuit performs:
a first step of storing a detection result of an abnormality detection circuit as first information, the first information indicating a latest detection result of the abnormality detection circuit, in a first storage region that stores the first information; and
a second step of storing the detection result of the abnormality detection circuit as second information, the second information indicating a detection history of the abnormality detected by the abnormality detection circuit, in a second storage region that is provided corresponding to the first storage region and stores the second information, and
in a case where the detection result of the abnormality detection circuit does not indicate an abnormality, the integrated circuit performs only the first step and not the second step.
